(19) United States
(12) Patent Application Publication
(10) Pub. No.: US 2007/0215959 A1
(43) Pub. Date: Sep. 20, 2007

(54) Semiconductor structures including accumulations of silicon boronide and related methods

(76) Inventors: Jin-Wook Lee, Gyeonggi-do (KR); Chang-Woo Ryoo, Gyeonggi-do (KR); Tai-Su Park, Gyeonggi-do (KR); U-In Chung, Seoul (KR); Yu-Gyun Shin, Gyeonggi-do (KR)

Correspondence Address: MYERS BIGEL SIBLEY & SAJOVEC, PO BOX 37428, RALEIGH, NC, 27627, US

(21) Appl. No.: 11/713,877

(22) Filed: Mar. 5, 2007

(30) Foreign Application Priority Data
Mar. 8, 2006 (KR) 2006-21581

(51) Int. Cl. H01L 29/94

(52) U.S. Cl. 257/412

(57) ABSTRACT

A semiconductor device may include a semiconductor substrate, first and second source/drain regions on a surface of the semiconductor substrate, and a channel region on the surface of the semiconductor substrate with the channel region between the first and second source/drain regions. An insulating layer pattern may be on the channel region, a first conductive layer pattern may be on the insulating layer, and a second conductive layer pattern may be on the first conductive layer pattern. The insulating layer pattern may be between the first conductive layer pattern and the channel region, and the first conductive layer pattern may include boron doped polysilicon with a surface portion having an accumulation of silicon boronide. The first conductive layer pattern may be between the second conductive layer pattern and the insulating layer pattern, and the second conductive layer pattern may include tungsten. Related methods are also discussed.

### RELATED APPLICATION

This application claims benefit of priority under 35 U.S.C. § 119 from Korean Patent Application No. 10-2006-0021581 filed on Mar. 8, 2006, in the Korean Intellectual Property Office, the disclosure of which is hereby incorporated herein by reference in its entirety.

### FIELD OF THE INVENTION

The present invention relates to electronics, and more particularly, to semiconductor structures and related methods.

### BACKGROUND

A gate structure of a transistor may include an insulating layer pattern, a conductive layer pattern, an adhesion film pattern, a barrier film pattern and a conductive film pattern. More particularly, the conductive layer pattern may be formed on the insulating layer pattern. The conductive layer pattern may include polysilicon doped with boron. An ion source including BF₃ may be used in an ion implantation to dope boron into the conductive layer pattern.

The adhesion film pattern may be formed on the conductive layer pattern, and the adhesion film pattern may include tungsten silicide. The barrier film pattern may be formed on the adhesion film pattern, and the barrier film pattern may include tungsten nitride. A conductive film pattern including tungsten may be formed on the barrier film pattern.

Reactivity between tungsten and silicon may be relatively high. If tungsten in the adhesion film pattern reacts with silicon in the conductive layer pattern, a defect such as a crack may be generated in the barrier film pattern.

### SUMMARY

According to some embodiments of the present invention, a semiconductor device may include a semiconductor substrate and an insulating layer pattern on the substrate. A first conductive layer pattern may be on the insulating layer pattern so that the insulating layer pattern is between the first conductive layer pattern and the substrate, and the first conductive layer pattern may include boron doped polysilicon and a surface portion having an accumulation of silicon boronide. A second conductive layer pattern may be on the first conductive layer pattern so that the first conductive layer pattern is between the second conductive layer pattern and the insulating layer pattern, and the second conductive layer pattern may include tungsten. In addition, first and second source/drain regions may be on a surface of the semiconductor substrate on opposite sides of the first conductive layer pattern, and a channel region may be on the surface of the semiconductor substrate between the first and second source/drain regions.

The surface portion of the first conductive layer pattern may have a first concentration of boron, and a portion of the boron doped polysilicon adjacent the insulating layer pattern may have a second concentration of boron. Moreover, the first concentration may be significantly greater than the second concentration.

An adhesion film pattern may be between the first and second conductive layer patterns with the adhesion film pattern including tungsten silicide, and a barrier film pattern may be between the adhesion film pattern and the second conductive layer pattern with the barrier film pattern including tungsten nitride. In addition, a second adhesion film pattern may be between the barrier film pattern and the second conductive layer pattern, and the second adhesion film pattern may include tungsten silicide. More particularly, the adhesion film pattern may have a thickness of about 5 nm, the barrier film pattern may have a thickness of about 5 nm, and/or the second adhesion film pattern may have a thickness of about 5 nm.

The surface portion of the first conductive layer pattern may have an accumulation of SiB₄ and/or SiB₆. Moreover, the first conductive layer pattern may have a thickness of about 60 nm, and the second conductive layer pattern may have a thickness of about 50 nm.

According to additional embodiments of the present invention, a semiconductor device may include a semiconductor substrate, first and second source/drain regions on a surface of the semiconductor substrate, and a channel region on the surface of the semiconductor substrate with the channel region being between the first and second source/drain regions. A gate insulating layer pattern may be on the channel region, and a first conductive layer pattern may be on the gate insulating layer pattern so that the gate insulating layer pattern is between the first conductive layer pattern and the channel region with the first conductive layer pattern including doped polysilicon. An adhesion film pattern may be on the first conductive layer pattern so that the first conductive layer pattern is between the adhesion film pattern and the gate insulating layer pattern with the adhesion film pattern including tungsten silicide. A barrier film pattern may be on the adhesion film pattern so that the adhesion film pattern is between the barrier film pattern and the first conductive layer pattern with the barrier film pattern including tungsten nitride. A second conductive layer pattern may be on the barrier film pattern so that the barrier film pattern is between the second conductive layer pattern and the adhesion film pattern with the second conductive layer pattern including tungsten.

The first conductive layer pattern may include a surface portion adjacent the adhesion film pattern with the surface portion having an accumulation of silicon boronide. More particularly, the surface portion may have an accumulation of SiB₄ and/or SiB₆. Moreover, the first conductive layer pattern may include boron doped polysilicon, the surface portion of the first conductive layer may have a first concentration of boron, a portion of the boron doped polysilicon adjacent the gate insulating layer may have a second concentration of boron, and the first concentration may be significantly greater than the second concentration. In addition, a second adhesion film pattern may be between the barrier film pattern and the second conductive layer pattern, and the second adhesion film pattern may include tungsten silicide.

According to still other embodiments of the present invention, a method of forming a semiconductor device may include forming an insulating layer on a semiconductor substrate and forming a first conductive layer on the insulating layer so that the insulating layer is between the first conductive layer and the semiconductor substrate. More particularly, the first conductive layer may include boron doped polysilicon and a surface portion having an accumulation of silicon boronide. A second conductive layer may be formed on the first conductive layer so that the first conductive layer is between the second conductive layer and the insulating layer with the second conductive layer including tungsten. The insulating layer and the first and second conductive layers may be patterned. In addition, first and second source/drain regions may be formed on opposite sides of the patterned first conductive layer.

Forming the first conductive layer may include forming a polysilicon layer and doping the polysilicon layer using a beam of ions including boron. More particularly, forming the polysilicon layer may include forming an n-type polysilicon layer, and/or the beam of ions may include B₁₈H₂₂ and/or B₁₀H₁₂. A source of the ions may be in a gaseous state, the beam of ions may include boron provided at an dose in the range of about 3*10¹⁶ ion/cm² to about 6*10¹⁶ ion/cm², and/or the beam of ions including boron may be provided at an energy in the range of about 40 keV to about 60 keV.

The surface portion of the first conductive layer may have a first concentration of boron, a portion of the boron doped polysilicon adjacent the insulating layer may have a second concentration of boron, and the first concentration may be significantly greater than the second concentration. Moreover, the surface portion of the first conductive layer pattern may have an accumulation of SiB₄ and/or SiB₆.

Before forming the second conductive layer, an adhesion film may be formed on the first conductive layer so that the first conductive layer is between the adhesion film and the insulating layer with the adhesion film including tungsten silicide. In addition, a barrier film may be formed on the adhesion film so that the barrier film is between the adhesion film and the second conductive layer with the barrier film including tungsten nitride. Before forming the second conductive layer, a second adhesion film may be formed on the barrier film so that the second adhesion film is between the barrier film and the second conductive layer with the second adhesion film including tungsten silicide.

According to some embodiments of the present invention, a transistor may include a barrier film pattern having a reduced number of defects such as cracks.

According to some embodiments of the present invention, a transistor may include a first source/drain region, a second source/drain region, a channel region, an insulating layer pattern, a first conductive layer pattern and a second conductive layer pattern. The channel region may be provided between the first and second source/drain regions. The insulating layer pattern may be provided on the channel region. The first conductive layer pattern may be provided on the insulating layer pattern. The conductive first layer pattern may include polysilicon doped with a boron cluster ion. The first conductive layer pattern may have a surface where a silicon boronide accumulates. The second conductive layer pattern may include tungsten and may be provided on the first conductive layer pattern.

The surface of the first conductive layer pattern may include a first concentration of the silicon boronide. The remaining portion of the first conductive layer pattern may include a second concentration of the silicon boronide, and the second concentration may be substantially less than the first concentration.

The second conductive layer pattern may include a first adhesion film pattern, a barrier film pattern, and a conductive film pattern. The first adhesion film pattern may include tungsten silicide. The barrier film pattern may be provided on the first adhesion film pattern, and the barrier film pattern may include tungsten nitride. The conductive film pattern may be provided on the barrier film pattern. The conductive film pattern may include tungsten. The second conductive layer pattern may further include a second adhesion film pattern between the barrier film pattern and the conductive film pattern.

According to some other embodiments of the present invention, a method of manufacturing a transistor may include forming an insulating layer on a semiconductor substrate, and forming a preliminary first conductive layer may be formed on the insulating layer. The preliminary first conductive layer may include polysilicon. A boron cluster ion may be doped into the preliminary first conductive layer using a cluster ion beam doping process to form a first conductive layer having a surface where a silicon boronide is accumulated. A second conductive layer may be formed on the first conductive layer, and the second conductive layer may include tungsten. A mask layer pattern may be formed on the second conductive layer. The second conductive layer, the first conductive layer, and the insulating layer may be etched to form a gate structure including a second conductive layer pattern, a first conductive layer pattern, and an insulating layer pattern. A portion of the semiconductor substrate exposed by the gate structure may be doped with an impurity to form a first source/drain region and a second source/drain region.

A surface of the first conductive layer may have a first concentration of the silicon boronide. A remaining portion of the first conductive layer may have a second concentration of the silicon boronide, and the second concentration may be substantially less than the first concentration.

An ion source used in the cluster ion beam doping process may include B₁₈H₂₂, B₁₀H₁₂, and/or a combination thereof. The ion source may be in a gaseous state.

The cluster ion beam doping process may be performed using a chamber having an upper electrode and a lower electrode, and the semiconductor substrate may be provided on the lower electrode. A voltage difference between the upper electrode and the lower electrode may be in the range of about 40 keV to about 60 keV. A number (dose) of the boron cluster ions may be in the range of about 3×10¹⁶ ion/cm² to about 6×10¹⁶ ion/cm².

The second conductive layer may include a first adhesion film, a barrier film and a conductive film. The adhesion film may include tungsten silicide. The barrier film may be formed on the first adhesion film, and the barrier film may include tungsten nitride. The conductive film may be formed on the barrier film.

The conductive film may include tungsten. The second conductive layer may further include a second adhesion film including tungsten silicide, and the second adhesion film may be formed between the barrier film and the conductive film. The preliminary conductive layer may include an N-type impurity providing an electron.

According to some embodiments of the present invention, a reaction between tungsten included in a first adhesion film pattern and silicon included in a first conductive layer pattern may be efficiently reduced. If a barrier film pattern including tungsten nitride is formed on the first adhesion film pattern, generation of defects such as cracks at the barrier film pattern may be reduced.

### BRIEF DESCRIPTION OF THE DRAWINGS

FIG. 1 is a cross-sectional view illustrating a transistor according to some embodiments of the present invention.

FIGS. 2 to 5 are cross-sectional views illustrating methods of manufacturing the transistor of FIG. 1 according to some embodiments of the present invention.

FIG. 6 is a cross-sectional view illustrating a transistor according to some other embodiments of the present invention.

FIGS. 7 to 8 are cross-sectional views illustrating methods of manufacturing the transistor of FIG. 6 according to some embodiments of the present invention.

FIG. 9 is a graph illustrating inversion capacitances.

### DETAILED DESCRIPTION

Embodiments of the present invention will be described with reference to the accompanying drawings. The present invention may, however, be embodied in many different forms and should not be construed as limited to the embodiments set forth herein. Rather, the embodiments are provided so that disclosure of the present invention will be thorough and complete, and will fully convey the scope of the present invention to those skilled in the art. Principles and/or features of the present invention may be employed in varied and numerous embodiments without departing from the scope of the present invention. In the drawings, the sizes and relative sizes of layers and regions may be exaggerated for clarity. The drawings are not to scale. Like reference numerals designate like elements throughout the drawings.

It will also be understood that when an element or layer is referred to as being “on,” “connected to” and/or “coupled to” another element or layer, the element or layer may be directly on, connected and/or coupled to the other element or layer or intervening elements or layers may be present. In contrast, when an element is referred to as being “directly on,” “directly connected to” and/or “directly coupled to” another element or layer, no intervening elements or layers are present. As used herein, the term “and/or” may include any and all combinations of one or more of the associated listed items.

It will also be understood that, although the terms first, second, etc. may be used herein to describe various elements, components, regions, layers and/or sections, these elements, components, regions, layers and/or sections should not be limited by these terms. These terms may be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular terms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof.

Unless otherwise defined, all terms (including technical and scientific terms) used herein may have the same meaning as what is commonly understood by one of ordinary skill in the art. It will be further understood that terms, such as those defined in commonly used dictionaries, should be interpreted as having a meaning that is consistent with their meaning in the context of this specification and the relevant art and will not be interpreted in an idealized and/or overly formal sense unless expressly so defined herein.

Embodiments of the present invention are described with reference to cross-sectional illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated as a rectangle will, typically, have rounded or curved features. Thus, the regions illustrated in the figures are schematic in nature of a device and are not intended to limit the scope of the present invention.

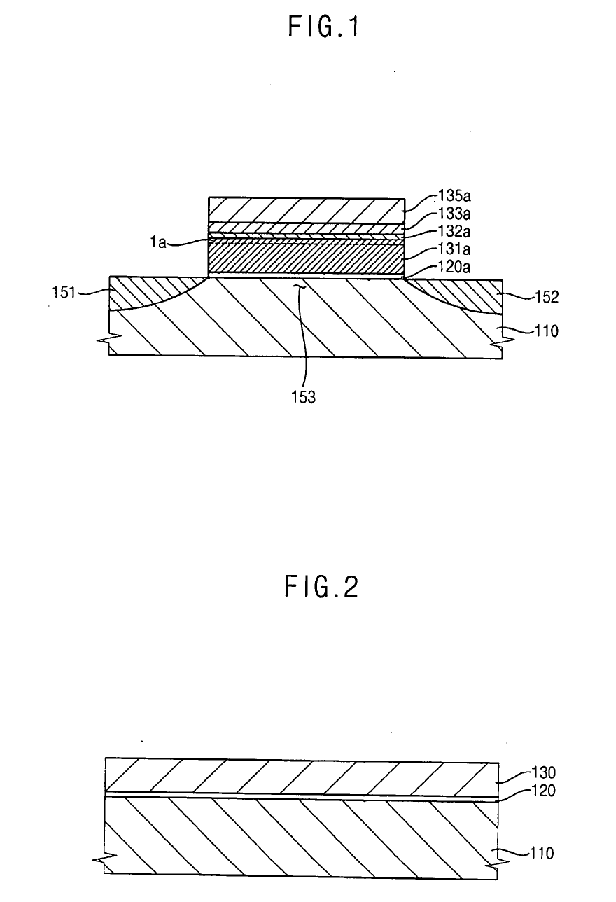

FIG. 1 is a cross-sectional view illustrating a transistor according to some embodiments of the present invention. Referring to FIG. 1, a transistor may include a first source/drain region 151, a second source/drain region 152, a channel region 153, an insulating layer pattern 120a, a conductive layer pattern 131a, a first adhesion film pattern 132a, a barrier film pattern 133a and a conductive film pattern 135a.

The first source/drain region 151 and the second source/drain region 152 may be provided in a surface of a semiconductor substrate 110. A portion of the semiconductor substrate 110 located between the first source/drain region 151 and the second source/drain region 152 may correspond to a channel region 153. The semiconductor substrate 110 may include silicon. The insulating layer pattern 120a is provided on the channel region 153, and the insulating layer pattern 120a may include an insulating material such as silicon oxide. A thickness of the insulating layer pattern 120a may be about 5 nm.

A surface of the insulating layer pattern 120a may be nitrided. If the surface of the insulating layer pattern 120a is nitrided, a material such as an ion and/or a metal may not readily diffuse into the semiconductor substrate 110 through the insulating layer pattern 120a.

The conductive layer pattern 131a may be provided on the insulating layer pattern 120a, and a thickness of the conductive layer pattern 131a may be about 60 nm. The conductive layer pattern 131a may include a P-type (positive type) impurity providing a hole, and the P-type impurity may be boron (B). The conductive layer pattern 131a may have a surface region 1a where a silicon boronide such as silicon tetraboronide (SiB₄) or silicon hexaboronide (SiB₆) may accumulate.

More particularly, the surface region 1a of the conductive layer pattern 131a may include a first concentration of the silicon boronide. The remaining portions of the conductive layer pattern 131a may include a second concentration of the silicon boronide, and the second concentration may be less than the first concentration.

The first adhesion film pattern 132a may be provided on the conductive layer pattern 131a, and the first adhesion film pattern 132a may include tungsten silicide (WSi). A thickness of the first adhesion film pattern 132a may be about 5 nm, and the first adhesion film pattern 132a may more firmly attach the barrier film pattern 133a to the conductive layer pattern 131a. In addition, the first adhesion film pattern 132a may reduce a contact resistance between the barrier film pattern 133a and the conductive layer pattern 131a.

The barrier film pattern 133a may include tungsten nitride (WN), and a thickness of the barrier film pattern 133a may be about 5 nm. The barrier film pattern 133a may reduce downward diffusion of a conductive material included in the conductive film pattern 135a. The conductive material included in the conductive film pattern 135a may be tungsten, and a thickness of the conductive film pattern 135a may be about 50 nm.

Reactivity between tungsten and silicon may be relatively high so that if tungsten in the first adhesion film pattern 132a reacts with silicon in the conductive layer pattern 131a, a defect such as a crack may be generated in the barrier film pattern 133a. According to some embodiments of the present invention, however, the surface region 1a of the conductive layer pattern 130a (where the silicon boronide such as SiB₄ or SiB₆ accumulates) may reduce reaction between tungsten in the first adhesion film pattern 132a and silicon in the conductive layer pattern 131a. As a result, defects such as cracks at the barrier film pattern 133a may be reduced.

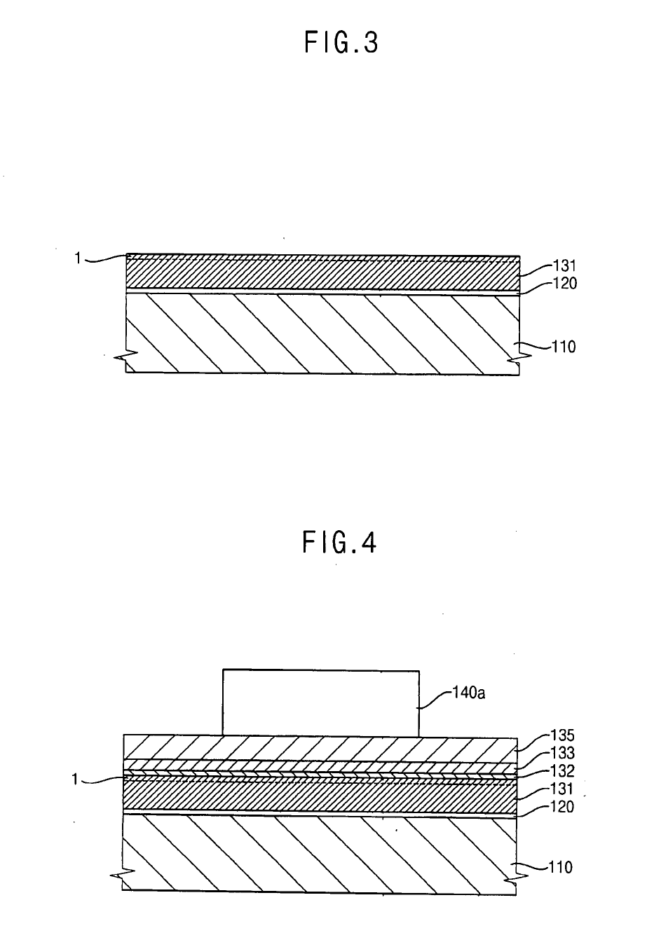

FIGS. 2 to 5 are cross-sectional views illustrating methods of manufacturing the transistor in FIG. 1. Referring to FIG. 2, an insulating layer 120 may be formed on a semiconductor substrate 110. The semiconductor substrate 100 may be a silicon substrate or a silicon-on-insulator (SOI) substrate, and the insulating layer 120 may include an insulating material such as silicon oxide. If the semiconductor substrate 110 includes silicon, the insulating layer 120 may be formed by a thermal oxidation process. A thickness of the insulating layer 120 may be about 5 nm.

A surface of the insulating layer 120 may be nitrided. If the surface of the insulating layer 120 is nitrided, a material such as an ion and/or a metal may not readily diffuse into the semiconductor substrate 110 through the insulating layer 120. For example, the surface of the insulating layer 120 may be nitrided using a plasma nitridation process.

A preliminary conductive layer 130 may be formed on the insulating layer 120. The preliminary conductive layer 130 may include polysilicon, and a thickness of the preliminary conductive layer 130 may be about 60 nm. The preliminary conductive layer 130 may not include an impurity. In an alternative, the preliminary conductive layer 130 may include an N-type (negative type) impurity providing an electron, and the N-type impurity may be phosphorus (P), arsenic (As), and/or antimony (Sb). Each of these impurities may be used alone or in a combination. If the preliminary conductive layer 130 includes an N-type impurity, the N-type impurity may be doped into the preliminary conductive layer 130 in-situ.

Referring to FIG. 3, a P-type impurity providing a hole may be implanted into the preliminary conductive layer 130. Thus, the preliminary conductive layer 130 may be transformed into a conductive layer 131. The P-type impurity may include boron (B), and the P-type impurity may be doped into the preliminary conductive layer 130 using a cluster ion beam doping process. In this case, the first conductive layer 131 may have a surface region 1a where silicon boronide (such as silicon tetraboronide SiB₄ and/or silicon hexaboronide SiB₆) may accumulate. More particularly, the surface region 1 of the conductive layer 131 may include a first concentration of the silicon boronide. Remaining portions of the conductive layer 131 may include a second concentration of the silicon boronide, and the second concentration may be less than the first concentration.

An ion source used in the cluster ion beam doping process may include B₁₈H₂₂ and/or B₁₀H₁₂. These ion sources may be used alone or in combination. In addition, the ion source may be in a gaseous state. The cluster ion beam doping process may be performed using a chamber having an upper electrode and a lower electrode, and the semiconductor substrate 110 may be provided on the lower electrode. If a voltage difference between the upper electrode and the lower electrode is less than about 40 keV, an inversion capacitance of the conductive layer 131 may be relatively small, and a distribution of the inversion capacitance may not be uniform. If the voltage difference between the upper electrode and the lower electrode is more than about 60 keV, boron may be implanted into the semiconductor substrate 110 through the insulating layer 120. Thus, the voltage difference between the upper electrode and the lower electrode may be in the range of about 40 keV to about 60 keV. For example, the voltage difference between the upper electrode and the lower electrode may be about 50 keV.

If a number (dose) of boron cluster ions doped into the first preliminary conductive layer 131 during the cluster ion beam doping process is less than about 3×10^{16 ion/cm}² the inversion capacitance may be relatively small, and a distribution of the inversion capacitance may not be uniform. If the number of the boron cluster ions doped into the first preliminary conductive layer 131 is greater than about 6×10¹⁶ ion/cm², defects may be generated at a surface of the conductive layer 131 thereby deteriorating a surface characteristic of the conductive layer 131. Thus, a number (dose) of the boron cluster ions doped into the first preliminary conductive layer 130 may be in the range of about 3×10¹⁶ ion/cm² to about 6×10¹⁶ ion/cm². For example, a number (dose) of the boron cluster ions doped into the first preliminary conductive layer 130 may be about 5×10¹⁶ ion/cm².

Referring to FIG. 4, a first adhesion film 132, a barrier film 133, a conductive film 135 and a mask layer pattern 140a may be successively formed on the conductive layer 131. The first adhesion film 132 may include tungsten silicide (WSi), and a thickness of the first adhesion film 132 may be about 5 nm. The first adhesion film 132 may more firmly attach the barrier film 133 to the conductive layer 131. In addition, the first adhesion film 132 may reduce a contact resistance between the barrier film 133 and the conductive layer 131.

The barrier film 133 may include tungsten nitride (WN), and a thickness of the barrier film 133 may be about 5 nm. The barrier film 133 may reduce downward diffusion of a conductive material included in the conductive film 135. The conductive material included in the conductive film 135 may be tungsten, and a thickness of the conductive film 135 may be about 50 nm. The mask layer pattern 140a may include silicon nitride, and a thickness of the mask layer pattern 140a may be about −200 nm.

Reactivity between tungsten and the silicon may be relatively high. If tungsten included in the first adhesion film 132 reacts with silicon included in the conductive layer 131, defects such as cracks may be generated at the barrier film 133. According to some embodiments of the present invention, however, the surface region 1 of the conductive layer 131 where the silicon boronide (such as SiB₄ and/or SiB₆) is accumulated may reduce reaction between tungsten included in the first adhesion film 132 and silicon included in the conductive layer 131. Accordingly, generation of defects such as cracks may at the barrier film 133 may be reduced.

Referring to FIG. 5, the conductive film 135, the barrier film 133, the first adhesion film 132, the conductive layer 131, and the insulating layer 120 may be successively etched using the mask layer pattern 140a as an etch mask. Thus, the conductive film 135, the barrier film 133, the first adhesion film 132, the conductive layer 131, and the insulating layer 120 may be transformed into a conductive film pattern 135a, a barrier film pattern 133a, a first adhesion film pattern 132a, a conductive layer pattern 131a, and an insulating layer pattern 120, respectively. The conductive layer pattern 131a may have a surface region 1a where the silicon boronide (such as SiB₄ and/or SiB₆) may accumulate.

An impurity may be doped into a surface of the semiconductor substrate 110 using the mask layer pattern 140a as an ion implantation mask. Thus, a first source/drain region 151 and a second source/drain region 152 may be formed in a surface of the semiconductor substrate 110. A portion of the semiconductor substrate 110 between the first source/drain region 154 and the second source/drain region 152 may correspond to a channel region 153. Thus, a transistor including the first source/drain region 151, the second source/drain region 152, the channel region 153, the insulating layer pattern 120a, the conductive layer pattern 131a, the first adhesion film pattern 132a, the barrier film pattern 133a, and the conductive film pattern 135a may be manufactured.

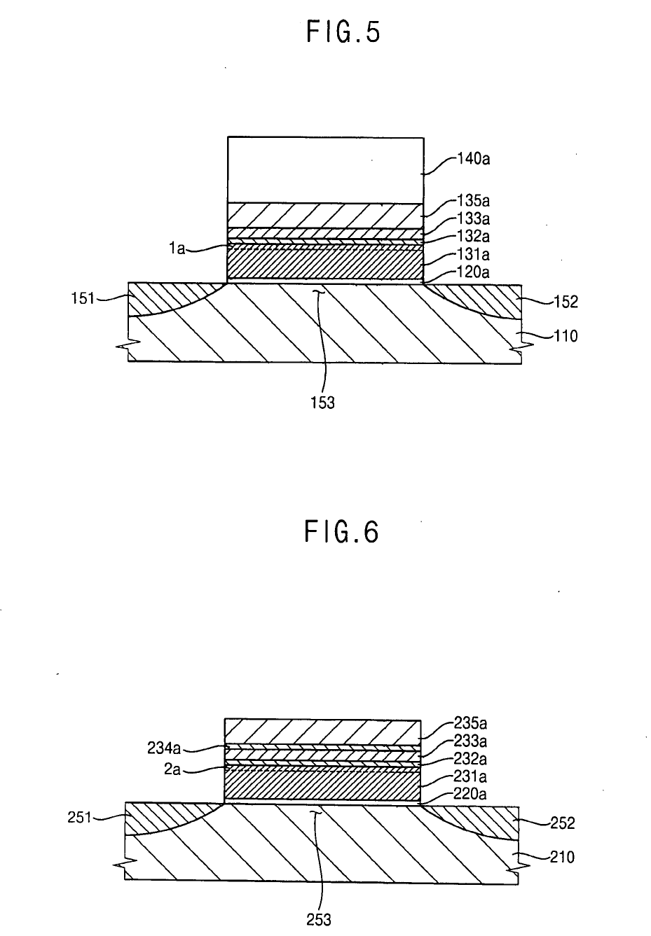

FIG. 6 is a cross-sectional view illustrating a transistor according to second embodiments of the present invention. The transistor of FIG. 6 is similar to that of FIG. 1 except for the addition of a second adhesion film pattern 234a. Repetitive explanation of common elements will thus be omitted.

Referring to FIG. 6, the transistor includes a first source/drain region 251, a second source/drain region 252, a channel region 253, an insulating layer pattern 220a, a conductive layer pattern 231a, a first adhesion film pattern 232a, a barrier film pattern 233a, a second adhesion film pattern 234a, and a conductive film pattern 235a.

The second adhesion film pattern 234a may be provided between the barrier film pattern 233a and the conductive film pattern 235a. The second adhesion film pattern 234a may include tungsten silicide, and a thickness of the second adhesion film pattern 234a may be about 5 nm. The second adhesion film pattern 234a may more firmly attach the conductive film pattern 235a to the barrier film pattern 233a. In addition, the second adhesion film pattern 234a may reduce a contact resistance between the conductive film pattern 235a and the barrier film pattern 233a.

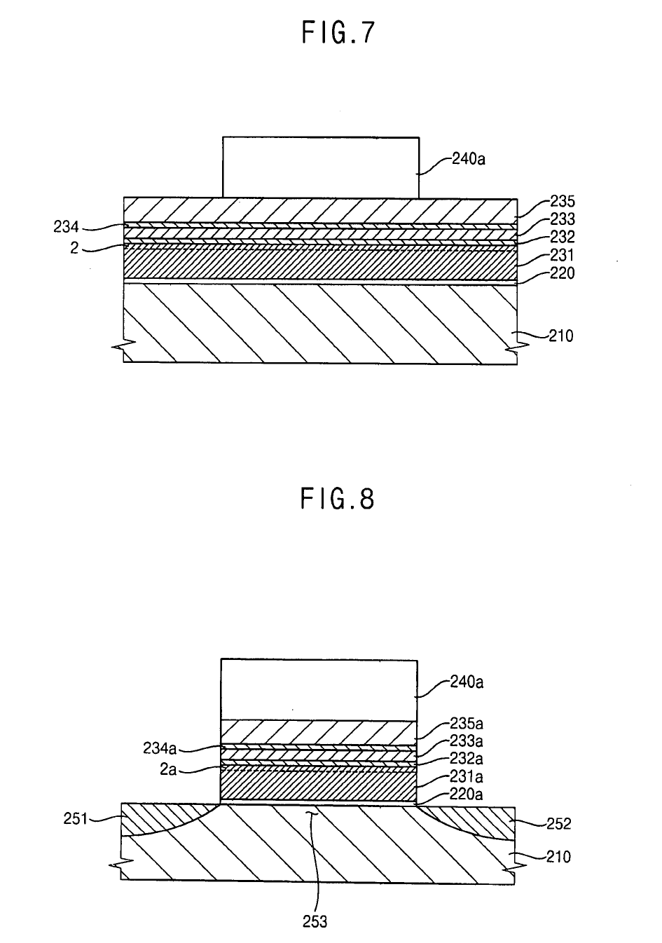

FIGS. 7 to 8 are cross-sectional views illustrating methods of manufacturing the transistor in FIG. 6. Referring to FIG. 7, an insulating layer 220, a conductive layer 231, a first adhesion film 232, and a barrier film 233 may be successively formed on a semiconductor substrate 210. The conductive layer 231 may have a surface 2 where a silicon boronide such as SiB₄ and/or SiB₆ may accumulate. Operations of forming the insulating layer 220, the conductive layer 231, the first adhesion film 232 and the barrier film 233 may be substantially the same as those already discussed with respect to the insulating layer 120, the conductive layer 131, the adhesion film 132, and the barrier film 133 of FIGS. 2 to 4. Further explanation will thus be omitted for the sake of conciseness.

A second adhesion film 234, a conductive film 235, and a mask layer pattern 240a may be successively formed on the barrier film 233. The second adhesion film 234 may include tungsten silicide, and a thickness of the second adhesion film 234 may be about 5 nm. The second adhesion film 234 may more firmly attach the conductive film 235 to the barrier film 233. In addition, the second adhesion film 234 may reduce a contact resistance between the conductive film 235 and the barrier film 233. Operations for forming the conductive film 235 and the mask layer pattern 240a may be substantially the same as those already discussed with respect to the conductive film 135 and the mask layer pattern 140a of FIG. 4. Further explanation will thus be omitted for the sake of conciseness.

Referring to FIG. 8, the conductive film 235, the second adhesion film 234, the barrier film 233, the first adhesion film 232, the conductive layer 231, and the insulating layer 220 may be successively etched using the mask layer pattern 240a as an etch mask. Thus, the conductive film 235, the second adhesion film 234, the barrier film 233, the first adhesion film 232, the conductive layer 231, and the insulating layer 220 may be transformed into a conductive film pattern 235a, a second adhesion film 234a, a barrier film pattern 233a, a first adhesion film pattern 232a, a conductive layer pattern 231a, and an insulating layer pattern 220a, respectively. The conductive layer pattern 231a may have a surface region 2a where a silicon boronide (such as SiB₄ or SiB₆) may accumulate.

An impurity may be implanted into a surface of the semiconductor substrate using the mask layer pattern 240a as an ion implantation mask. Thus, a first source/drain region 251 and a second source/drain region 252 may be formed in the surface of the semiconductor substrate 210. A portion of the semiconductor substrate 210 between the first source/drain region 251 and the second source/drain region 252 may correspond to a channel region 253.

Thus, a transistor including the first source/drain region 251, the second source/drain region 252, the channel region 253, the insulating layer pattern 220a, the conductive layer pattern 231a, the first adhesion film pattern 232a, the barrier film pattern 233a, the second adhesion film pattern 234a, and the conductive film pattern 235a may be manufactured.

Inversion Capacitance

A transistor including a first source/drain region, a second source/drain region, a channel region, an insulating layer pattern, a conductive layer pattern, a first adhesion film pattern, a barrier film pattern, a second adhesion film pattern, and a conductive film pattern may be provided as discussed above with respect to FIGS. 6-8.

The insulating layer pattern may include silicon oxide, and a thickness of the insulating layer pattern may be about 5 nm. The conductive layer pattern may include polysilicon doped with a boron cluster ion, and a thickness of the conductive layer pattern may be about 60 nm. The first adhesion film pattern may include tungsten silicide, and a thickness of the first adhesion film pattern may be about 5 nm. The barrier film pattern may include tungsten nitride, and a thickness of the barrier film pattern may be about 10 nm. The second adhesion film pattern may include tungsten silicide, and a thickness of the second adhesion film may be about 5 nm. The conductive film may include tungsten, and a thickness of the conductive film may be about 50 nm.

More particularly, the conductive layer pattern may be formed by etching a conductive layer formed using an ion cluster beam doping process on a preliminary conductive layer including polysilicon. The cluster ion beam doping process may be performed using a chamber having an upper electrode and a lower electrode and an ion source used in the cluster ion beam doping process may include B₁₈H₂₂.

In a primary example, a voltage difference between the upper electrode and the lower electrode may be about 50 keV, and a number (dose) of a boron cluster ions doped into the first preliminary conductive layer may be about 5×10¹⁶ ion/cm². In Comparative Example 1, a voltage difference between the upper electrode and the lower electrode may be about 30 keV, and a number (dose) of the boron cluster ions doped into the first preliminary conductive layer may be about 5×10¹⁶ ion/cm². In Comparative Example 2, a voltage difference between the upper electrode and the lower electrode may be about 50 keV, and a number (dose) of the boron cluster ions doped into the first preliminary conductive layer may be about 1.6×10¹⁶ ion/cm². In Comparative Example 3, a voltage difference between the upper electrode and the lower electrode may be about 50 keV, and a number of the boron cluster ions doped into the first preliminary conductive layer may be about 2×10¹⁶ ion/cm².

Inversion capacitances and distributions of the inversion capacitances of transistors having structures according to the primary Example, Comparative Example 1, Comparative Example 2 and Comparative Example 3 were determined.

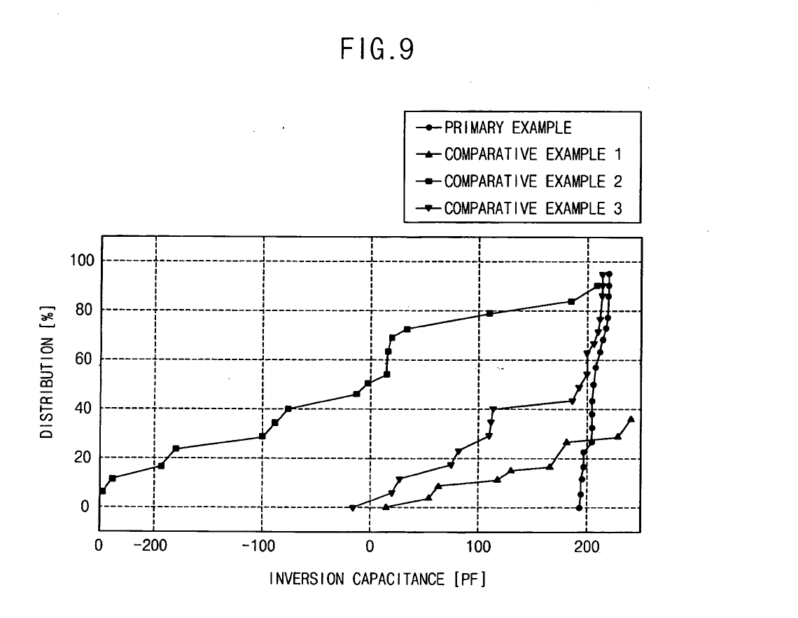

FIG. 9 is a graph showing inversion capacitances of transistors having the structures discussed above. Referring to FIG. 9, an inversion capacitance of a transistor having a structure of the Primary Example may be about 200 pF. That is, the inversion capacitance of a transistor having the structure of the Primary Example may be relatively high. In addition, an inversion capacitance of a transistor according to the Primary Example may be relatively constant at about 200 pF. That is, a distribution of the inversion capacitance may be satisfactory.

An inversion capacitance of a transistor having the structure of Comparative Example 1 may be relatively low. In addition, an inversion capacitance of a transistor according to Comparative Example 1 may not be constant.

An inversion capacitance of a transistor having the structure of Comparative Example 2 may be relatively low. In addition, an inversion capacitance of a transistor according to Comparative Example 2 may not be constant.

An inversion capacitance of a transistor having the structure of Comparative Example 3 may be relatively low. In addition, an inversion capacitance of a transistor according to Comparative Example 3 may not be constant.

According to embodiments of the present invention, a reaction between tungsten included in a first adhesion film pattern and silicon included in a conductive layer pattern may be efficiently reduced. If a barrier film pattern including tungsten nitride is formed on a first adhesion film pattern, generation of defects such as cracks at the barrier film pattern may be reduced.

The foregoing is illustrative of embodiments of the present invention and is not to be construed as limiting thereof. Although a few embodiments of this invention have been described, those skilled in the art will readily appreciate that many modifications are possible in the embodiments without materially departing from the novel teachings and/or advantages of this invention. Accordingly, all such modifications are intended to be included within the scope of this invention as defined in the claims. Therefore, it is to be understood that the foregoing is illustrative of embodiments of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A semiconductor device comprising:
a semiconductor substrate;
an insulating layer pattern on the substrate;
a first conductive layer pattern on the insulating layer pattern so that the insulating layer pattern is between the first conductive layer pattern and the substrate, wherein the first conductive layer pattern includes boron doped polysilicon and a surface portion having an accumulation of silicon boronide; and
a second conductive layer pattern on the first conductive layer pattern so that the first conductive layer pattern is between the second conductive layer pattern and the insulating layer pattern, wherein the second conductive layer pattern includes tungsten.

2. The semiconductor device according to claim 1 further comprising:
first and second source/drain regions on a surface of the semiconductor substrate on opposite sides of the first conductive layer pattern; and
a channel region on the surface of the semiconductor substrate, wherein the channel region is between the first and second source/drain regions.

3. The semiconductor device according to claim 1 wherein the surface portion of the first conductive layer pattern has a first concentration of boron, wherein a portion of the boron doped polysilicon adjacent the insulating layer pattern has a second concentration of boron, and wherein the first concentration is significantly greater than the second concentration.

4. The semiconductor device according to claim 1 further comprising:
an adhesion film pattern between the first and second conductive layer patterns; and
a barrier film pattern between the adhesion film pattern and the second conductive layer pattern.

5. The semiconductor device according to claim 4 wherein the adhesion film pattern includes tungsten silicide, and wherein the barrier film pattern includes tungsten nitride.

6. The semiconductor device according to claim 4 wherein the adhesion film pattern has a thickness of about 5 nm and wherein the barrier film pattern has a thickness of about 5 nm.

7. The semiconductor device according to claim 4 further comprising:
a second adhesion film pattern between the barrier film pattern and the second conductive layer pattern.

8. The semiconductor device according to claim 7 wherein the second adhesion film pattern comprises tungsten silicide.

9. The semiconductor device according to claim 7 wherein the second adhesion film pattern has a thickness of about 5 nm.

10. The semiconductor device according to claim 1 wherein the surface portion of the first conductive layer pattern has an accumulation of SiB₄ and/or SiB₆.

11. The semiconductor device according to claim 1 wherein the first conductive layer pattern has a thickness of about 60 nm and wherein the second conductive layer pattern has a thickness of about 50 nm.

12. A semiconductor device comprising:
a semiconductor substrate;
first and second source/drain regions on a surface of the semiconductor substrate;
a channel region on the surface of the semiconductor substrate, wherein the channel region is between the first and second source/drain regions;
a gate insulating layer pattern on the channel region;
a first conductive layer pattern on the gate insulating layer pattern so that the gate insulating layer pattern is between the first conductive layer pattern and the channel region, wherein the first conductive layer pattern includes doped polysilicon;
an adhesion film pattern on the first conductive layer pattern so that the first conductive layer pattern is between the adhesion film pattern and the gate insulating layer pattern, wherein the adhesion film pattern includes tungsten silicide;
a barrier film pattern on the adhesion film pattern so that the adhesion film pattern is between the barrier film pattern and the first conductive layer pattern, wherein the barrier film pattern includes tungsten nitride; and
a second conductive layer pattern on the barrier film pattern so that the barrier film pattern is between the second conductive layer pattern and the adhesion film pattern, wherein the second conductive layer pattern includes tungsten.

13. The semiconductor device according to claim 12 wherein the first conductive layer pattern includes a surface portion adjacent the adhesion film pattern wherein the surface portion has an accumulation of silicon boronide.

14. The semiconductor device according to claim 13 wherein the surface portion has an accumulation of SiB₄ and/or SiB₆.

15. The semiconductor device according to claim 13 wherein the first conductive layer pattern includes boron doped polysilicon and wherein the surface portion of the first conductive layer has a first concentration of boron, wherein a portion of the boron doped polysilicon adjacent the gate insulating layer has a second concentration of boron, and wherein the first concentration is significantly greater than the second concentration.

16. The semiconductor device according to claim 12 further comprising:
a second adhesion film pattern between the barrier film pattern and the second conductive layer pattern, wherein the second adhesion film pattern includes tungsten silicide.

17. A method of forming a semiconductor device, the method comprising:
forming an insulating layer on a semiconductor substrate;
forming a first conductive layer on the insulating layer so that the insulating layer is between the first conductive layer and the semiconductor substrate, wherein the first conductive layer includes boron doped polysilicon and a surface portion having an accumulation of silicon boronide;
forming a second conductive layer on the first conductive layer so that the first conductive layer is between the second conductive layer and the insulating layer, wherein the second conductive layer includes tungsten;
patterning the insulating layer and the first and second conductive layers.

18. The method according to claim 17, further comprising:
forming first and second source/drain regions on opposite sides of the patterned first conductive layer.

19. The method according to claim 17 wherein forming the first conductive layer includes forming a polysilicon layer and doping the polysilicon layer using a beam of ions including boron.

20. The method according to claim 19 wherein forming the polysilicon layer includes forming an n-type polysilicon layer.

21. The method according to claim 19 wherein the beam of ions includes B₁₈H₂₂ and/or B₁₀H₁₂.

22. The method according to claim 21 wherein a source of the ions is in a gaseous state.

23. The method according to claim 19 wherein the beam of ions including boron is provided at an dose in the range of about 3*10¹⁶ ion/cm² to about 6*10¹⁶ ion/cm².

24. The method according to claim 19 wherein the beam of ions including boron is provided at an energy in the range of about 40 keV to about 60 keV.

25. The method according to claim 17 wherein the surface portion of the first conductive layer has a first concentration of boron, wherein a portion of the boron doped polysilicon adjacent the insulating layer has a second concentration of boron, and wherein the first concentration is significantly greater than the second concentration.

26. The method according to claim 17 further comprising:
before forming the second conductive layer, forming an adhesion film on the first conductive layer so that the first conductive layer is between the adhesion film and the insulating layer, wherein the adhesion film includes tungsten silicide; and
forming a barrier film on the adhesion film so that the barrier film is between the adhesion film and the second conductive layer, wherein the barrier film includes tungsten nitride.

27. The method according to claim 26 further comprising:
before forming the second conductive layer, forming a second adhesion film on the barrier film so that the second adhesion film is between the barrier film and the second conductive layer, wherein the second adhesion film includes tungsten silicide.

28. The semiconductor device according to claim 17 wherein the surface portion of the first conductive layer pattern has an accumulation of SiB₄ and/or SiB₆.
